(19) United States
(12) Patent Application Publication
(10) Pub. No.: US 2008/0130232 A1
(43) Pub. Date: Jun. 5, 2008

(54) HEAT SINK

(75) Inventors: Tsutomu YAMAMOTO, Hino City (JP); Yoshihisa HATOZAKI, Kobe City (JP)

Correspondence Address: ROSSI, KIMMS & McDOWELL LLP., P.O. BOX 826, ASHBURN, VA, 20146-0826, US

(73) Assignee: Fuji Electric FA Components & Systems Co., Ltd., Tokyo (JP)

(21) Appl. No.: 11/946,331

(22) Filed: Nov. 28, 2007

(30) Foreign Application Priority Data
Nov. 30, 2006 (JP) 2006-322725

(51) Int. Cl. H05K 7/20

(52) U.S. Cl. 361/703

(57) ABSTRACT

A heat sink is provided that can prevent the velocity of air flowing between fins in the vicinity of the component mounting space from decreasing. In the heat sink, a plurality of fins and the component mounting space are disposed on a fin unit side of the base. A lateral-end fin portion in the vicinity of the component mounting space is provided with an opening for taking in air and discharging air from a side.

### BACKGROUND

The present invention relates to a heat sink, and more particularly to a heat sink for an inverter unit that converts alternating-current power from a commercial power supply or the like into alternating-current power with a predetermined frequency and voltage and feeds the resultant power to an electric motor or the like.

FIG. 4 is a diagram showing a typical circuit configuration of an inverter unit of the above-mentioned type. The inverter unit 10 in FIG. 4 is comprised of a converter 11 that rectifies alternating-current voltage applied from a commercial power supply or the like via a terminal 19a of a terminal block 19 (see FIG. 5), an electrolytic capacitor 12 that smoothes the rectified voltage, an inverter 14 that converts the smoothed voltage across the electrolytic capacitor 12 into alternating-current voltage with a desired frequency and outputs the resultant voltage via a terminal 19b of the terminal block 19, a control circuit 15 that provides controls to bring an IGBT and others constituting the inverter 14 to desired operating states, and a DC/DC converter 16 serving as a power supply circuit that produces a gate power supply for the inverter 14 and a control power supply for the control circuit 15. In FIG. 4, reference numeral 13 denotes a resistance discharge circuit comprised of a damping resistor 13a, a transistor 13b, and so on for preventing the voltage across the electrolytic capacitor 12 from increasing to a predetermined value or greater due to regenerative electric power from loads of the inverter unit 10 or the like. An example of inverter units of this type in which a damping resistor is mounted on an air guide plate provided on the fin distal end side of a heat sink so as to cool the damping resistor is disclosed in Japanese Laid-Open Patent Publication (Kokai) No. 2004-187462.

On the other hand, there has been a case where a component mounting space for mounting therein a damping resistor is provided on the fin side of a heat sink, and this will now be described with reference to FIGS. 5 to 8. FIG. 5 is a sectional view showing a conventional inverter apparatus having the inverter unit 10 incorporated therein, FIG. 6 is a perspective view showing the heat sink as viewed from above, FIG. 7 is a perspective view showing the heat sink as viewed from below, and FIG. 8 is a bottom view showing the heat sink. In FIGS. 5 to 8, reference numeral 20 denotes a heat sink, in which heating components such as the converter 11 and the inverter 14 are disposed on one surface of a base 22, a plurality of flat-shaped fins 22 are arranged substantially parallel at regular spacings on the other surface of the base 21, and a component mounting space 23 for mounting therein components such as the damping resistor 13a is formed in a part of the heat sink 20 on the fins 22 side.

As shown in FIG. 5, the terminal block 19, the electrolytic capacitor 12, an insulating transformer 16a and an electrolytic capacitor 16b constituting the DC/DC converter 16, and so on are disposed on a component mounting surface (front side) of a main conversion circuit/power supply circuit board 17 inside a case 1. The converter 11 and the inverter 14 comprised of power modules as main conversion circuits are disposed on the back side of the main conversion circuit/power supply circuit board 17, and one surface of each of the converter 11 and the inverter 14 is closely held on and fixed to a mounting surface of the base 22 of the heat sink 20. Further, the control circuit 15 appearing in FIG. 4 is disposed on a control circuit board 18, which is held by a case partition 2 secured to the case 1, so that heating of the main conversion circuit/power supply circuit board 17 is prevented from affecting the control circuit board 18.

In general, the inverter unit 10 is longitudinally mounted on an in-board mounting frame 3 with the terminal block 19 on the lower side, and the heat sink 20 dissipates heat produced from heating components through natural convection from below upward as viewed in FIG. 5. The heat sink 20 used for the inverter unit 10 is often manufactured using a method called aluminum die-casting particularly when a motor applied to the inverter unit 10 is small in capacity and size. As compared with a heat sink of a comb-like fin type manufactured by mounting an aluminum thin plate on a base surface through caulking or brazing, the heat sink 20 manufactured by aluminum die-casting has the advantage that it functions not only as a radiator but also as a mounting portion for various components, i.e. as a case.

In the case where the component mounting space 23 for mounting therein components such as a damping resistor is provided on the fin unit 22 side as in the conventional art, the problem arises in which the cooling air stagnates in an area A of the fin unit 22a, which is formed downstream of the component mounting space 23 as indicated by alternate long and short dashed lines in FIG. 8, and as a result, the rate of heat transfer over the surface of the fin unit 22 locally decreases.

### SUMMARY OF THE INVENTION

The present invention provides a heat sink that, even if a component mounting space is provided in part of a fin unit, can prevent the velocity of air flowing between fins located in the vicinity of the component mounting space from decreasing.

Specifically, the present invention provides a heat sink that includes a base, and a plurality of fin portions and a component mounting space disposed on a fin unit side of the base. A lateral-end fin portion of the fin portions in a vicinity of the component mounting space is provided with an opening for taking in air and discharging air. A flow path for a rising air current is formed by the opening and the fin portion around the opening, so that the formation of a cooling air detention area around the component mounting space can be suppressed to prevent the rate of transfer over the fin surface from decreasing, and also the amount of heat dissipated from the heat sink can be increased, resulting in an improvement in the heat dissipation performance of the heat sink. As a result, miniaturization of the heat sink which is required to control a rise in the temperature of the heating components to a predetermined value or less can be achieved, and accordingly, the cost of materials can be reduced.

The above and other objects, features, and advantages of the invention will become more apparent from the following detailed description taken in conjunction with the accompanying drawings.

### BRIEF DESCRIPTION OF THE DRAWINGS

The invention will be described with reference to certain preferred embodiments thereof and the accompanying drawings, wherein:

FIG. 1 is a perspective view showing a heat sink according to a first embodiment of the present invention;

FIG. 2 is a bottom view showing the heat sink according to the first embodiment;

FIG. 3 is a bottom view showing a heat sink according to a second embodiment of the present invention;

FIG. 4 is a diagram showing the circuit configuration of an inverter apparatus;

FIG. 5 is a sectional view showing a conventional inverter apparatus;

FIG. 6 is a perspective view showing a conventional heat sink as viewed from above;

FIG. 7 is a perspective view showing the conventional heat sink as viewed from below; and

FIG. 8 is a bottom view showing the conventional heat sink.

### DETAILED DESCRIPTION OF THE PREFERRED EMBODIMENTS

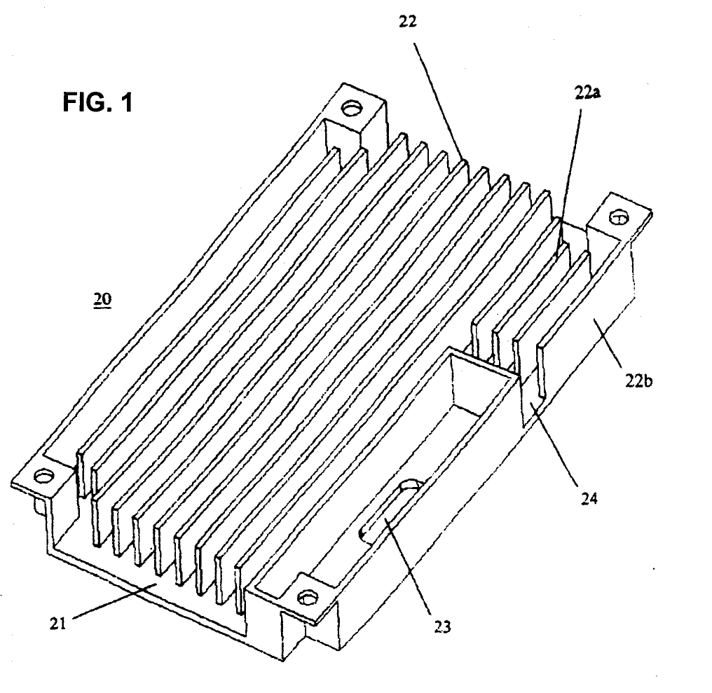

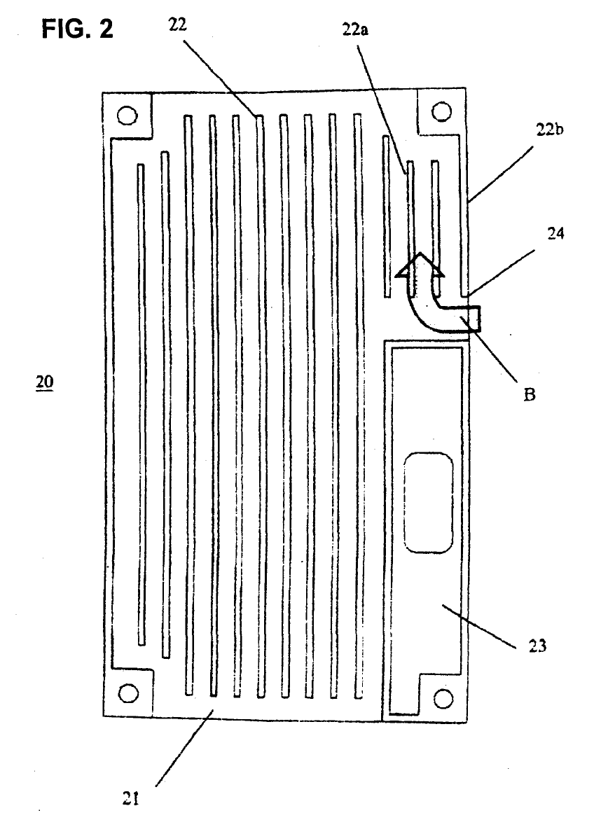

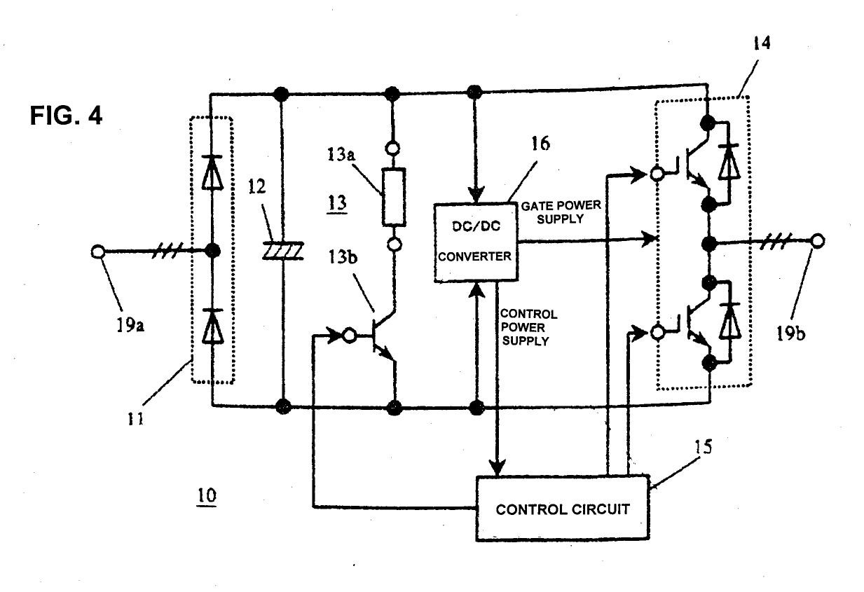

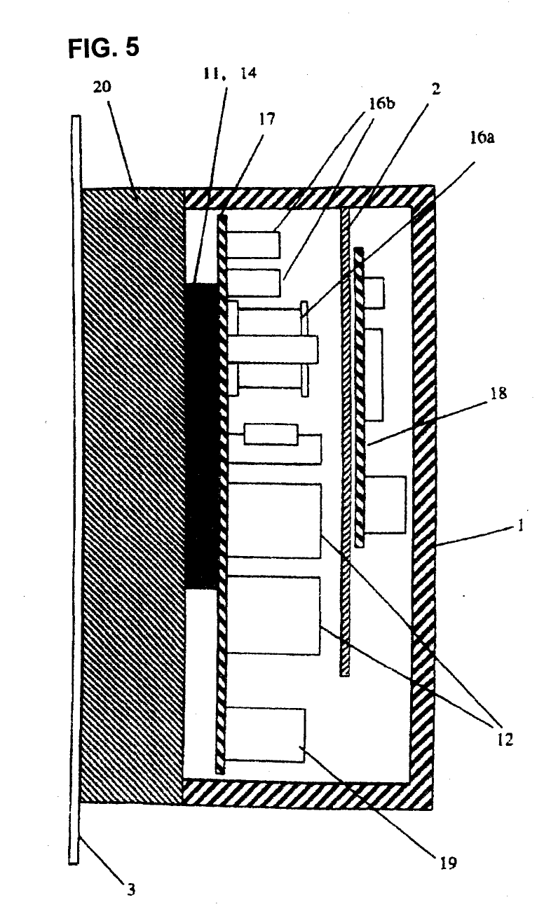

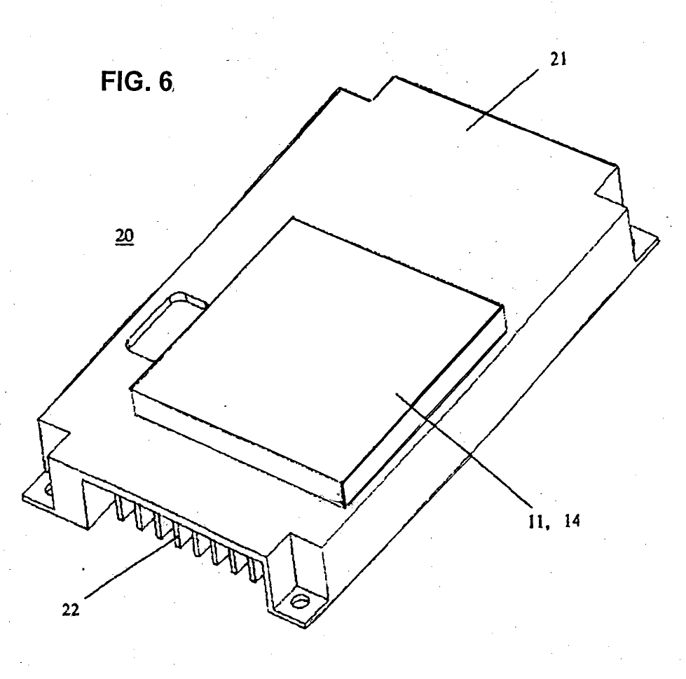

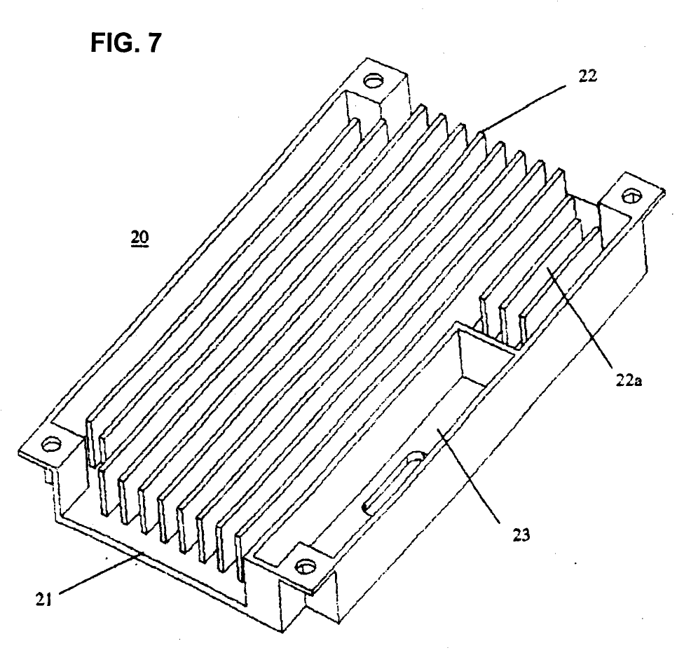

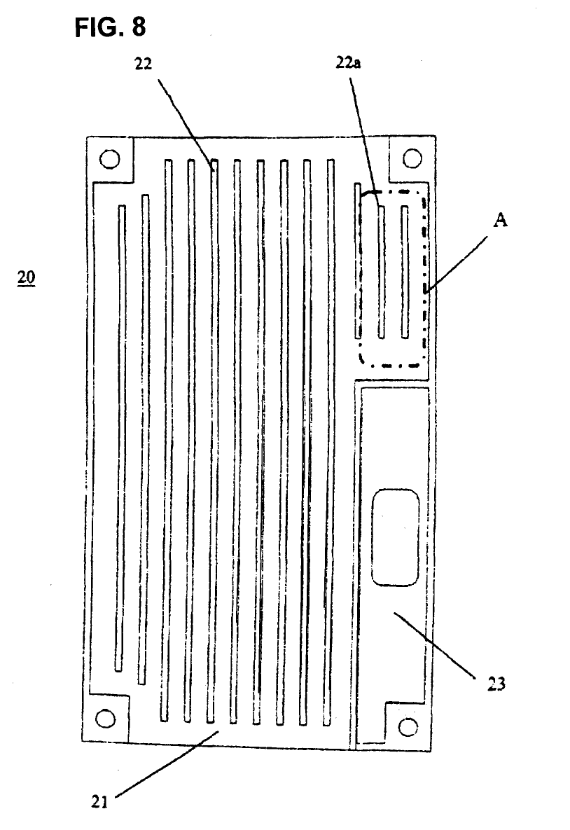

FIG. 1 is a perspective view showing a heat sink according to an embodiment of the present invention, and FIG. 2 is a bottom view showing the heat sink according to the embodiment. In FIGS. 1 and 2, the same members as those appearing in FIGS. 4 to 8 are denoted by the same reference numerals, and description thereof is omitted. As shown in FIGS. 1 and 2, on the upstream side of natural convection, a component mounting space 23 for mounting a damping resistor 13a therein is provided on the fin unit 22 side of the heat sink 20, and a fin portion section 22a is formed downstream of the component mounting space 23 and at a predetermined distance from the component mounting space 23. In FIGS. 1 and 2, reference numeral 22b denotes a lateral-end fin portion formed outside the fin unit 22; the lateral-end fin portion 22b as well as a case 1 (see FIG. 4) constitutes a package for an inverter apparatus and functions as a part of the package. The lateral-end fin portion 22b in the vicinity of the component mounting space 23 is provided with an air intake opening 24, which is in communication with an outer space.

Thus, for the air downstream of the component mounting space 23 with its density reduced due to a rise in temperature, there is formed a flow path for a rising air current B (shown in FIG. 2) of external air that is drawn in from the air intake opening 24 formed in the side of the heat sink 20 and flows upward. Accordingly, the provision of the air intake opening 24 to provide a flow path for the rising air current B eliminates an air detention area formed in the conventional heat sink and thus improves the heat dissipation performance of the heat sink 20.

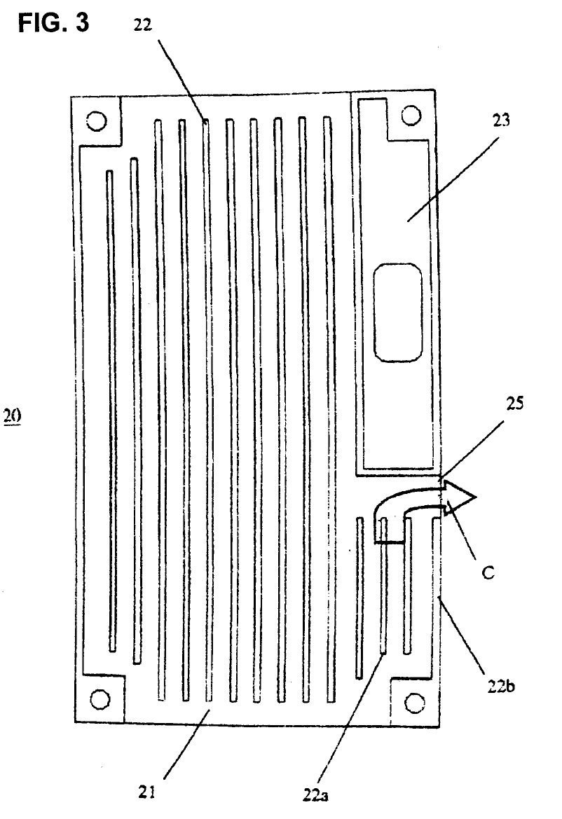

FIG. 3 is a bottom view showing a heat sink according to another embodiment of the present invention. Referring to FIG. 3, on the downstream side of natural convection, a component mounting space 23 for mounting a damping resistor 13a therein is provided on the fin unit 22 side of the heat sink, and a fin portion 22a is formed upstream of the component mounting space 23 and at a predetermined distance from the component mounting space 23. Moreover, a lateral-end fin portion 22b in the vicinity of the component mounting space 23 is provided with an air discharge opening 25 which is in communication with an outer space.

In the embodiment illustrated in FIG. 3, conversely to the embodiment illustrated in FIGS. 1 and 2, there is formed a flow path for a rising air current C flowing from the fin portion 22a to the outside through the air discharge opening 25. The provision of the air discharge opening 25 to provide a flow path for the rising air current C eliminates an air detention area formed in the conventional heat sink and thus improves heat dispassion performance of the heat sink.

The invention has been described with reference to certain preferred embodiments thereof. It will be understood, however, that modifications and variations are possible within the scope of the appended claims. For example, the illustrated embodiments show the air intake opening 24 and the air discharge opening 25 to be in the form of a substantially vertical slit or slot that extends through the entire thickness of the lateral-end fin portion 22b, but it will be understood that the opening may take any form (for example, lateral slits or slots, one or more holes, V-shaped cut, multiple slits instead of one, etc.) as long as sufficient air flow is provided to prevent the formation of an air detention area. Still further, while the heat sink is preferably manufactured using the above-described aluminum die-casting method, the invention is applicable to heat sinks manufactured by any process.

What is claimed is:

1. A heat sink comprising:
a base;
a plurality of fin portions and a component mounting space disposed on a fin unit side of the base;
wherein a lateral-end fin portion of the fin portions is provided with an opening in a vicinity of the component mounting space.

2. A heat sink as claimed in claim 1, wherein the lateral-end fin portion forms a side wall of the component mounting space.

3. A heat sink as claimed in claim 1, wherein the fin portions include a fin portion section comprising fins portions of substantially shorter length than the lateral-end fin portion, wherein the fin portion section is laterally aligned with the component mounting space.

4. A heat sink as claimed in claim 3, wherein the heat sink is configured in accordance with a defined flow direction, and wherein the fin portion section is located upstream of the component mounting space with respect to the defined flow direction.

5. A heat sink as claimed in claim 3, wherein the heat sink is configured in accordance with a defined flow direction, and wherein the fin portion section is located downstream of the component mounting space with respect to the defined flow direction.
